(19) United States
(12) Patent Application Publication
(10) Pub. No.: US 2013/0062720 A1
(43) Pub. Date: Mar. 14, 2013

(54) EXTENDED AREA COVER PLATE FOR INTEGRATED INFRARED SENSOR

(71) Applicants: Rick L. Wise, Fairview, TX (US); Kalin Valeriev Lazarov, Tucson, AZ (US); Karen Hildegard Ralston Kirmse, Richardson, TX (US); Kandis Meinel, Tucson, AZ (US)

(72) Inventors: Rick L. Wise, Fairview, TX (US); Walter Baker Meinel, Tucson, AZ (US); Kalin Valeriev Lazarov, Tucson, AZ (US); Karen Hildegard Ralston Kirmse, Richardson, TX (US)

(73) Assignee: TEXAS INSTRUMENTS INCORPORATED, Dallas, TX (US)

(21) Appl. No.: 13/412,563

(22) Filed: Mar. 5, 2012

Related U.S. Application Data
(60) Provisional application No. 61/449,307, filed on Mar. 4, 2011.

(51) Int. Cl. H01L 31/0203; H01L 31/18

(52) U.S. Cl. 257/434; 438/64; 257/E31.117

(57) ABSTRACT

An integrated circuit chip includes a window cover over etchant holes in a dielectric layer and over a cavity in the substrate of said integrated circuit chip. The window cover extends at least 400 microns beyond the edge of the cavity. An integrated sensor chip with a sensor cover which extends at least 400 microns beyond the edges of a cavity. A method of forming an integrated sensor chip with a sensor cover which extends at least 400 microns beyond the edge of a cavity.

### CROSS-REFERENCE TO RELATED APPLICATIONS

This application claims the benefit of priority under U.S.C. §119(e) of U.S. Provisional Application 61/449,307, filed Mar. 4, 2011, the entirety of which is herein incorporated by reference.

This invention relates to integrated sensors. More particularly, this invention relates to the attachment of sensor covers to integrated sensors.

### BACKGROUND

Top down and cross sectional views of a typical integrated IR sensor, such as the sensor described in US Patent Application Publication No. 2010/0213373 (Ser. No. 12/380,316, filed Feb. 26, 2009), the entirety of which is herein incorporated by reference, is shown in FIGS. 1A through 1C.

The integrated infrared (IR) sensor consists of a device whose electrical characteristics change in proportion to the amount of IR radiation incident upon the device. For example, the IR sensitive device may be thermocouples 40 and 48 as in FIG. 1C. In a typical integrated IR sensor, some of the IR sensitive devices, for example thermocouple 40 in FIG. 1C, may be suspended above a cavity 32 to thermally isolate it from the thermally conductive substrate 30. Other IR sensitive devices, for example thermocouple 48 in FIG. 1C, may be in contact with the thermally conductive substrate 30 and used as a control. In FIG. 1C, thermocouples 40 and 48 are connected in series to form a thermopile. Thermocouple 48 is in contact with the substrate and remains at the substrate reference temperature whereas thermocouple 40 is suspended in the cavity and either increases or decreases in temperature as the IR radiation density either increases or decreases.

FIG. 1A is a top down view of an IR sensor. The active IR sensor devices 40 which are embedded in the dielectric 20 and suspended above the cavity32 are located in area 26. Etchant holes 28 which extend through the dielectric down to the substrate 30 allow etchants in to etch away substrate to form the cavity 32. Sensor cover 24 is applied over the sensor cavity area to cover the holes to keep solvents and other debris from getting into the cavity during subsequent operations such as backgrind and wafer sawing. The sensor cover 24 also is reinforcement for the fragile suspended sensor area. The etchant access holes increase the fragility of the suspended area making it more prone to breakage which reduces yield. The sensor cover 24 may be a relatively thick epoxy film on the order of 14 microns which provides significant reinforcement to the fragile suspended area 26.

A cross section of the IR sensor shown in FIG. 1A through line 28 is shown in FIG. 1B. The IR sensor is built on semiconductor substrate 30. A series of dielectric layers 20 which may be silicon dioxide are formed on the substrate 30. The IR sensitive devices and interconnect layers may be formed within the dielectric layer. Contact holes 22 are formed through the dielectric 20 layer stack and filled with conductive material such as CVD-W to provide electrical contact to the substrate.

An expanded view of inset 36 in FIG. 1B is shown in FIG. 1C. The IR sensitive thermocouples 40 and 48 are formed within the dielectric layers 20. The thermocouples 40 and 48 are connected in series forming a thermopile IR sensor. When two dissimilar conductors are connected together a voltage is generated due to the differences in the Seebeck coefficients of the two dissimilar conductors. The lower conductor 42 of the thermopile may be doped polysilicon. The upper conductor 46 may be a metal such as aluminum or TiN. Tungsten plugs 44 and metal 1 interconnect 50 connect the two dissimilar conductors 42 and 46 to form thermocouple 40 which is suspended over the cavity 32. Similarly thermocouple 48 is formed over the substrate 30 and electrically connected with metal1 50 and metal2 54. Additional levels of interconnect 54 may be formed if integrated circuits 56 are also formed on the IR sensor chip. Since single crystal silicon is transparent to IR radiation, the IR source whose intensity is being measured may be located above the IR sensor so the IR radiation passes through the dielectric layers on its way to the IR sensor or may be located below where the IR radiation passes through the single crystal silicon substrate 30. Since the cavity 32 isolates the suspended thermocouple 40 from the thermally conductive substrate, thermocouple 40 will heat up more than thermocouple 48 which is in contact with the thermally conductive substrate. As the IR intensity is increased, the temperature difference between thermocouples 40 and 48 is increased which increases the output voltage from the thermopile. Logic circuits 56 may also be formed in the substrate 30, if desired. and the voltage output of the thermopile may be read by the integrated circuit and converted to a digital readout of temperature for example.

A typical backgrind process to thin the substrate 30 is shown in FIGS. 2A and 2B. As shown in FIG. 2A, backgrind tape 70 is applied to the topside of the wafer containing the integrated sensor chips to protect the topside of the integrated sensor and to hold the wafer in place during the backgrind process. After the substrate is background to the specified thickness the backgrind tape 70 is removed. Delamination of the sensor cover 24 during this tape removal process may occur, as shown in FIG. 2B. amd may reduce yield. Because the perforated sensor dielectric over the cavity is fragile, it sometimes breaks off and remains attached to the sensor cover when the sensor cover delaminates.

A typical bump process to form solder bumps on the integrated IR sensor is shown in FIGS. 3A through 3D. After the sensor cover 24 is attached to the integrated IR sensor over the suspended IR sensors over the cavity 32, a metallic adhesion and copper coating seed layer 80 is deposited as shown in FIG. 3A. In an example embodiment the metallic adhesion layer 80 is about 300 nm TiW with a thin (about 200 nm) copper seed layer sputtered on top of the TiW.

Referring now to FIG. 3B, an electroplating photo resist pattern 82 is formed over the metallic adhesion layer 80 with openings over the metal filled vias. The diameter of the vias typically is about 300 microns in diameter as opposed to 75 microns in diameter for typical wire bonding pads. Copper posts 84 are then electroplated on the TiW and copper seed layer 80 in the photo resist openings.

As shown in FIG. 3C, after the copper posts are formed the resist is removed and the TiW and copper seed layers 80 are etched away where not protected by copper posts.

Solder bumps 86 may then be formed on the copper posts using conventional methods as shown in FIG. 3D. The solder bumps 86 may be composed of lead-tin or gold-tin.

A problem with the bump process flow is that the sensor cover may sometimes delaminate resulting in defective integrated IR sensors which lowers the yield. This is especially problematic when the resist pattern must be stripped to rework the pattern. During the resist removal process the sensor cover may also be removed decreasing yield. In addition, an integrated IR sensor wafer that has been reworked is more prone to losing cover windows during the backgrind operation or during subsequent integrated IR sensor wafer or integrated IR sensor chip handling operations which may stress the top surface of the chips.

As shown in FIG. 1A, the integrated IR sensor may have a plurality of holes 28 through the dielectric 20 that is suspended over the cavity 32. The holes 28 decrease the strength of the dielectric layer under the sensor cover with the consequence that the suspended dielectric which is perforated with holes tends to break off if the sensor cover 24 delaminates such as during pattern rework, during backgrind, during packaging, or during the attachment of the integrated sensor chip to a circuit board.

### SUMMARY

An integrated circuit chip with a window cover over etchant holes and over a cavity in the substrate of said integrated circuit chip which extends at least 400 microns beyond the edge of the cavity. An integrated sensor chip with a sensor cover which extends at least 400 microns beyond the edges of a cavity. A method of forming an integrated sensor chip with a sensor cover which extends at least 400 microns beyond the edge of a cavity.

### BRIEF DESCRIPTION OF THE DRAWINGS

FIG. 1A (Prior art) is a top down view of an integrated sensor chip with a conventional sensor cover.

FIGS. 1B and 1C (Prior art) are cross-sections of an integrated sensor chip with a conventional sensor cover.

FIGS. 2A through 2B are illustrations of the steps in backgrind of an integrated sensor chip.

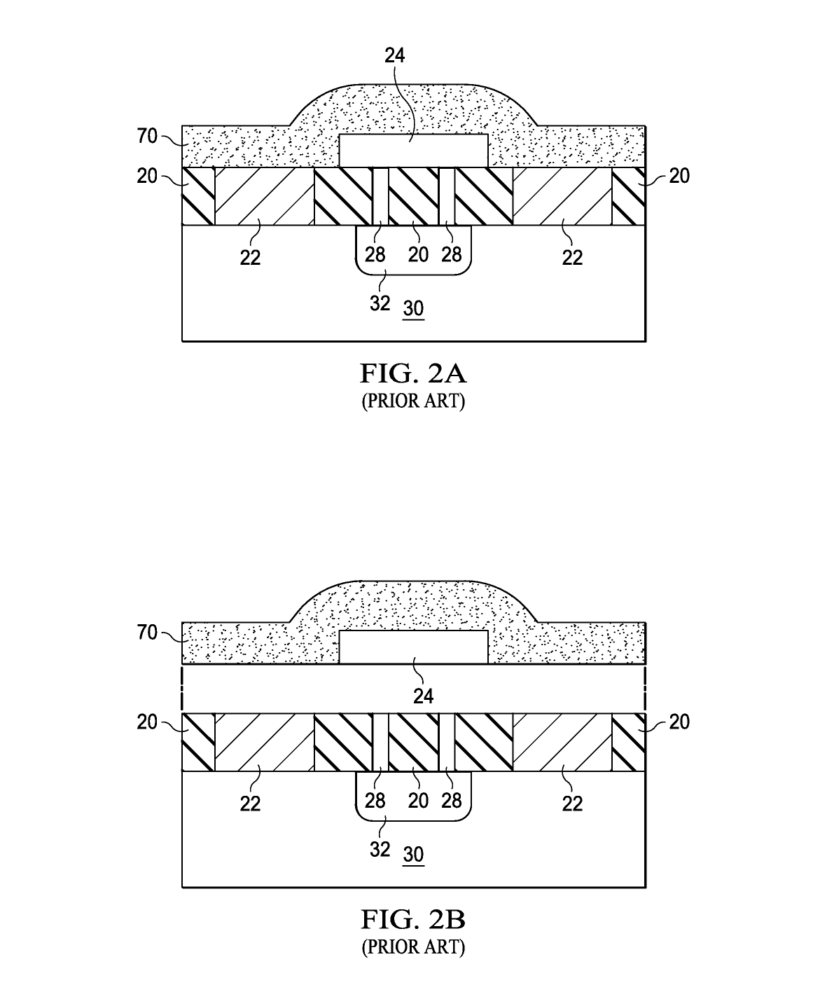

FIGS. 3A through 3D are illustrations of the steps in the fabrication of solder bumps on an integrated sensor chip.

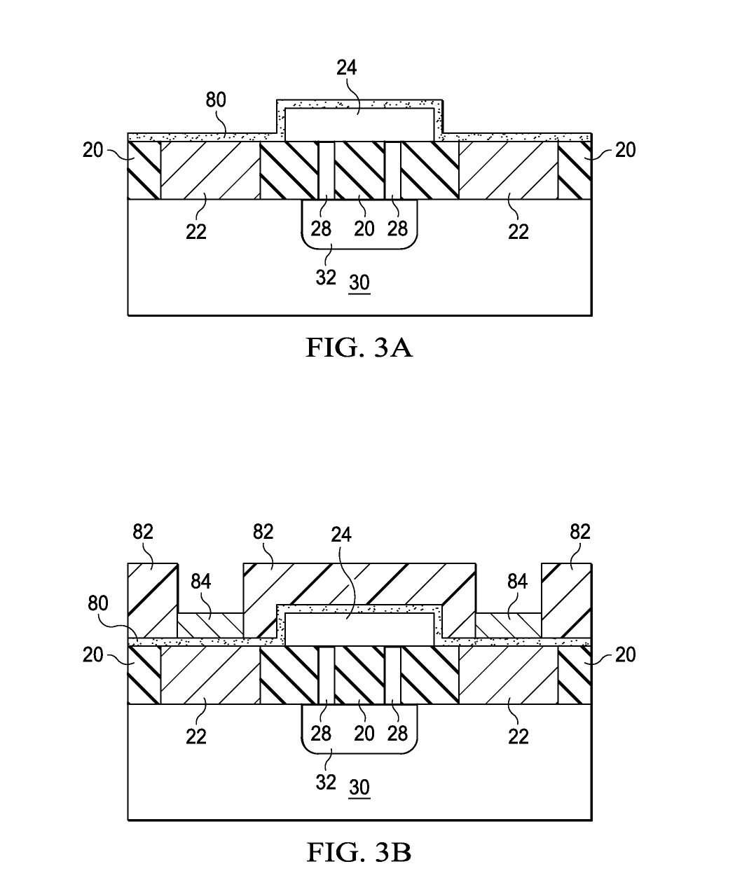

FIG. 4A is a cross-section of an integrated sensor chip with an embodiment sensor cover formed according to principles of the invention.

FIG. 4B is a top down view of an integrated sensor chip with an embodiment sensor cover formed according to principles of the invention.

### DETAILED DESCRIPTION OF EXAMPLE EMBODIMENTS

The term “integrated sensor” refers to a sensor which is embedded in an integrated circuit chip during the manufacture of the integrated circuit chip. For example, an integrated IR sensor chip may contain transistors, capacitors, and resistors in addition to IR sensitive thermopiles.

The term “integrated sensor chip” refers to an integrated circuit chip which contains an integrated sensor.

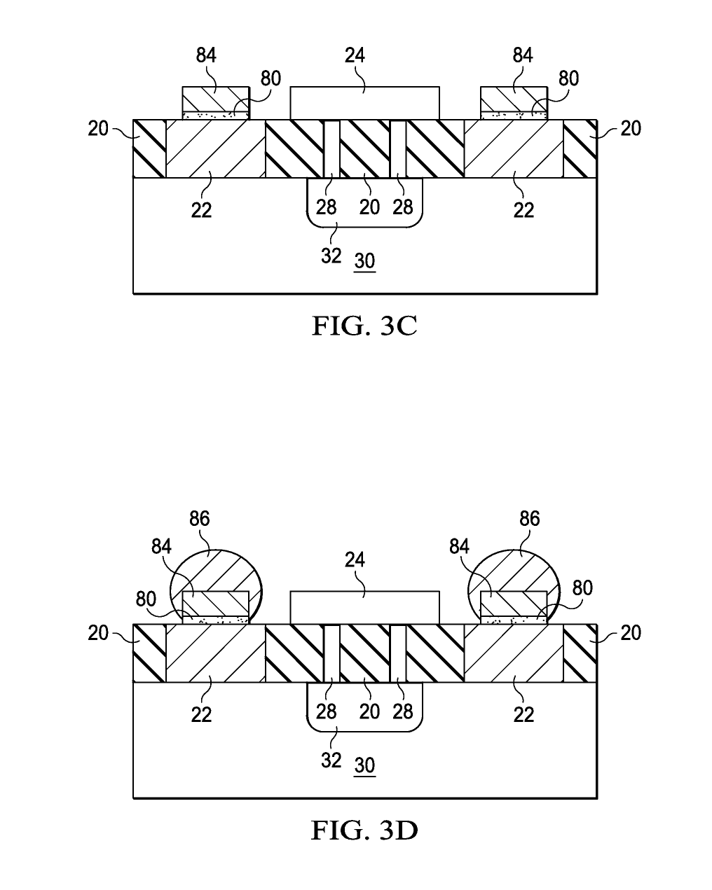

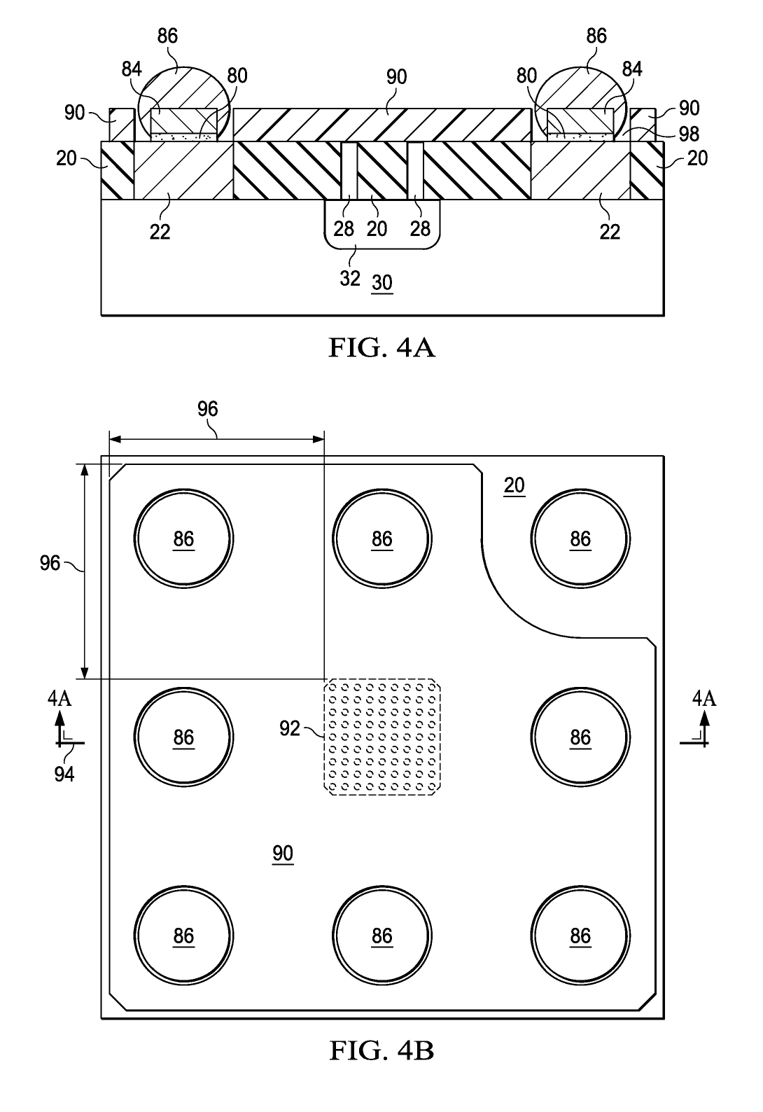

A cross sectional view of an integrated sensor with an embodiment sensor cover 90 is shown in FIG. 4A. The cross sectional view is taken along the line 94 in the top down view of an integrated sensor with an embodiment sensor cover 90 in FIG. 4B. An integrated IR sensor with an embodiment sensor cover 90 is used for illustration, but other sensor covers and other similar materials that may be applied to the surface of an integrated circuit may also benefit from these embodiments. The sensor cover 90 for the integrated IR sensor chip used to illustrate the embodiment may be a photosensitive epoxy film approximately 14 microns thick that may be applied to the surface of an integrated circuit chip in a manner similar to applying backgrind tape. This photosensitive epoxy film may be exposed with a photomask and developed to remove the epoxy film from the contact areas where bumps are to be formed. After develop, the epoxy film may be baked and exposed with UV light to crosslink and harden the epoxy film. Other similar cover layers that may be applied to a portion of the surface of an integrated circuit and that may be subject to delamination during subsequent processing such as backgrind or wafer sawing or subject to delamination during subsequent handling of the integrated circuit chip such as mounting on a circuit board or during use of the integrated circuit chip may also benefit from these embodiments

As shown in FIG. 4B the majority of the top surface of the integrated IR sensor is covered with the embodiment sensor cover 50. The embodiment sensor cover 90 extends almost to the edges of the integrated IR sensor chip. Electrical contacts to the integrated IR sensor are formed through via holes 98 in the example embodiment sensor cover 90. This significantly increases the area of the sensor cover 90 bonded to the surface of the integrated IR sensor which significantly increases the area where adhesive bonds the sensor cover 90 to the surface and which significantly reduces the incidence of delamination of the sensor cover 90 during subsequent processing such as rework, backgrind, and other handling of the IR sensor chip.

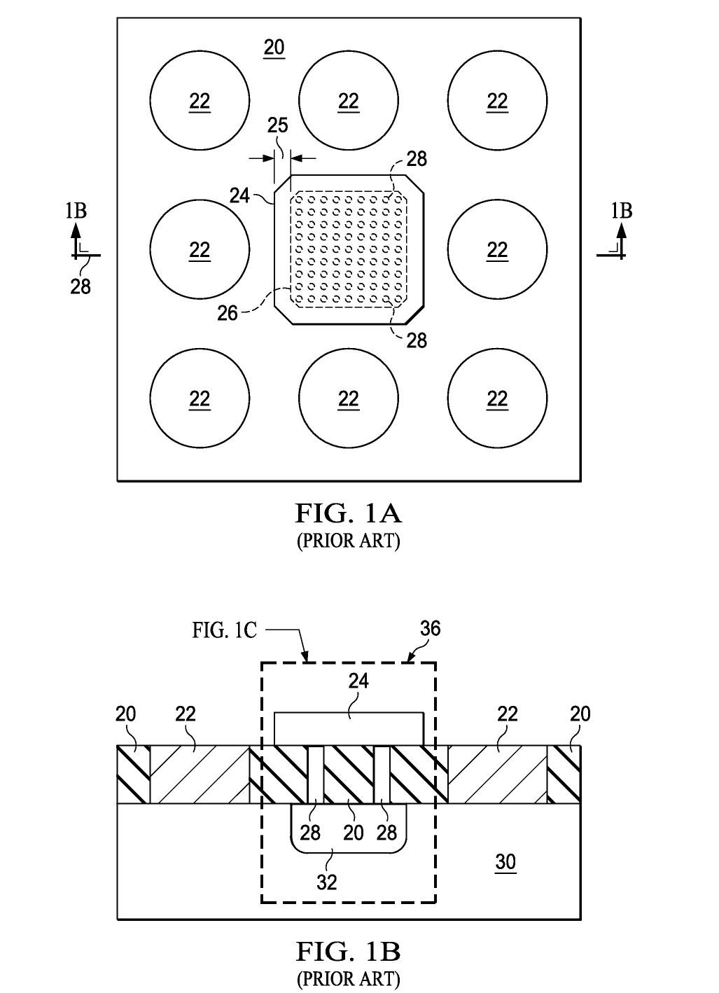

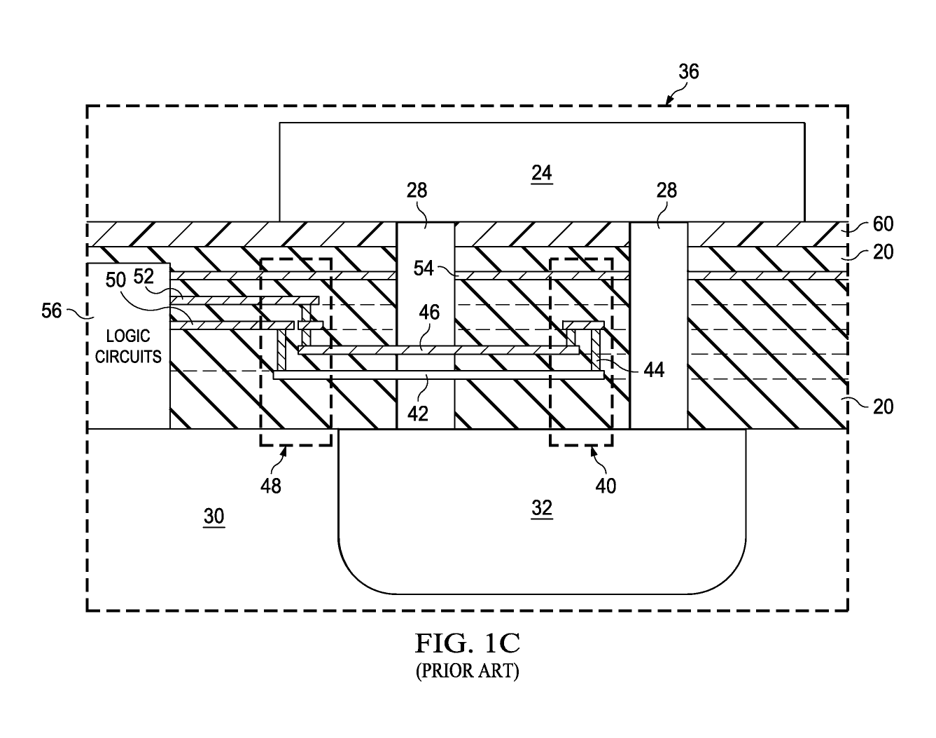

The length 25 that the IR sensor cover extends beyond the suspended dielectric sensor area 28 in a conventional integrated sensor chip illustrated in FIG. 1A may be about 1 micron to about 100 microns The length 96 that the embodiment sensor cover 90 in FIG. 4B extends beyond the suspended dielectric sensor area 92 may be greater than about 400 microns. In an example embodiment illustrated in FIG. 4B, the sensor cover overlaps the suspended dielectric sensor area 92 and extends nearly to the edges of the integrated sensor chip. Most of the top surface of the integrated sensor chip is covered by the sensor cover 90. Holes 98 are formed through the sensor cover 90 where the solder bumps are to be formed.

As shown in FIGS. 4A and 4B, most of the surface area of the integrated IR sensor chip outside the suspended perforated dielectric area 92 is bonded to the sensor cover 90. Sensor cover 90 virtually eliminates delamination of the sensor cover during bump processing and reworking of the integrated IR sensor. Sensor cover 90 also virtually eliminates sensor covers breaking off during subsequent handling of the integrated sensor chip which may stress the chip such as mounting it onto a circuit board and significantly improves reliability of the IR sensor during use.

Although an integrated circuit IR sensor is used to illustrate the embodiments any similar device to which a sensor cover or other similar cover material is applied to the surface of an integrated circuit chip and which may be contacted by backgrind tape, exposed to a resist reworking process, or may suffer yield loss due to delamination during handling may benefit from this embodiment. For example an integrated circuit chip may contain a plurality of closely spaced holes in the dielectric surface making the dielectric fragile and prone to breakage during subsequent operations such as backgrind or wafer sawing. An embodiment window cover may cover the dielectric area with the holes providing reinforcement. An embodiment window cover is less prone to delamination and breakage.

Those skilled in the art to which this invention relates will appreciate that many other embodiments and variations are possible within the scope of the claimed invention.

What is claimed is:

1. An integrated circuit chip, comprising:
a dielectric layer which overlies a substrate of said integrated sensor chip;
a cavity in said substrate underlying said dielectric layer;
a plurality of etchant holes through said dielectric layer and over said cavity; and
a window cover which overlies a first portion of said dielectric containing said plurality of etchant holes and extends at least about 400 microns beyond an edge of said cavity over a second portion of said dielectric containing no etchant holes.

2. The integrated circuit chip of claim 1 where said window cover is an epoxy film laminated to a top surface of said integrated circuit chip.

3. An integrated sensor chip, comprising:
a first sensor and a second sensor embedded in a dielectric layer which overlies a substrate of said integrated sensor chip;
a cavity in said substrate underlying said dielectric layer under said first sensor;
a plurality of etchant holes through said dielectric layer and over said cavity;
a sensor cover which overlies a first portion of said dielectric containing said plurality of etchant holes and said first sensor and extends at least about 400 microns beyond an edge of said cavity over a second portion of said dielectric containing no etchant holes.

4. The integrated sensor chip of claim 3 where said sensor detects infrared radiation.

5. The integrated sensor of claim 3 where said sensor cover extends to within about 100 microns of at least two edges of said integrated circuit chip.

6. The integrated sensor chip of claim 3 where said sensor cover contains via openings through which electrical contacts are made to said substrate.

7. The integrated sensor chip of claim 3 where said first sensor comprises a first thermocouple embedded in said dielectric layers and thermally decoupled from said substrate by said cavity and said second sensor comprises a second thermocouple embedded within dielectric layers overlying said substrate and thermally coupled to said substrate, and said first thermocouple and said second thermocouple are coupled together in series to form a thermopile.

8. The integrated sensor chip of claim 3 where said sensor cover is a photosensitive epoxy laminated film.

9. The integrated sensor chip of claim 8 where said photosensitive epoxy laminated film has a thickness in the range of about 10 microns to 30 microns.

10. A process of forming an integrated sensor chip with a sensor cover comprising the steps:
forming sensor elements which are sensitive to electromagnetic radiation embedded within dielectric layers overlying a substrate of said integrated sensor chip;
forming holes through said dielectric layers containing a first portion of said sensor elements;
introducing an etchant through said holes and etching a cavity in said substrate under said first portion to thermally decouple said first portion from said substrate where a second portion of said sensor elements remains thermally coupled to said substrate to form reference sensor elements;
applying said sensor cover over said first portion covering said holes where said sensor cover extends over a surface of said integrated sensor chip outside said first portion by at least about 400 microns on at least 2 sides.

11. The process of claim 10 where said sensor cover extends to within about 100 microns of edges of said integrated sensor chip.

12. The process of claim 10 further comprising the steps of forming openings through said sensor cover where electrical contacts are to be formed to said integrated sensor chip.

13. The process of claim 10 where said step of forming sensor elements further comprises:
depositing and etching a first conductive material to form a first lead;
depositing and etching a second conductive material to form a second lead; and
coupling a first end of said first lead to a first end of said second lead to form a first thermocouple where said first thermocouple is thermally decoupled from said substrate by said cavity;
coupling a second end of said first lead to a second end of said second lead to form a second thermocouple where said second thermocouple is thermally coupled to said substrate; and
coupling said first thermocouple to said second thermocouple in series to form a thermopile.

14. The process of claim 13 where said first conductive material is doped polysilicon and where said second conductive material is aluminum.

15. The process of claim 13 where said first conductive material is doped polysilicon and where said second conductive material is titanium nitride.

16. The process of claim 10 where said step of applying said sensor cover further comprises:
laminating a photosensitive epoxy film to the surface of said integrated sensor chip;
exposing said photosensitive epoxy film with a photomask to expose openings in said photosensitive epoxy film over contacts on said integrated sensor chip; and
developing said photosensitive epoxy film to remove exposed photosensitive epoxy from said openings.

17. The process of claim 13 where said sensor cover is a photosensitive epoxy film in the range of about 10 microns to about 16 microns thick.

18. The process of claim 13 where said sensor cover is a photosensitive epoxy film about 14 microns thick.
